(19) United States
(12) Patent Application Publication
(10) Pub. No.: US 2021/0336101 A1
(43) Pub. Date: Oct. 28, 2021

(54) Optoelectronic Device and Method for Manufacturing Optoelectronic Devices

(71) Applicant: OSRAM Opto Semiconductors GmbH, Regensburg (DE)

(72) Inventors: Albert Schneider, Thalmassing (DE); Kathy Schmidtke, Mainburg (DE); David Racz, Regensburg (DE)

(21) Appl. No.: 17/284,167

(22) PCT Filed: Oct. 9, 2019
(86) PCT No.: PCT/EP2019/077409

§ 371 Date: Apr. 9, 2021

(30) Foreign Application Priority Data
Oct. 15, 2018 (DE) 10 2018 125 506.3

(51) Int. Cl. H01L 33/50; H01L 33/60

(52) U.S. Cl. CPC H01L 33/505; H01L 2933/0058; H01L 2933/0041; H01L 33/60

(57) ABSTRACT

In an embodiment an optoelectronic device includes an optoelectronic component with a first main surface, a second main surface and a plurality of side surfaces interconnecting the first and second main surfaces and a conversion element arranged at the first main surface of the optoelectronic component, wherein the conversion element includes a frame of a reflective material and a conversion material located within the frame, wherein an interface between the frame and the conversion material runs slanted having an angle of smaller than 180° and larger than 90° between the interface and an adjacent side surface of the plurality of side surfaces, and wherein the frame protrudes laterally beyond a light emitting area of the first main surface of the optoelectronic component.

This patent application is a national phase filing under section 371 of PCT/EP2019/077409, filed Oct. 9, 2019, which claims the priority of German patent application 102018125506.3, filed Oct. 15, 2018, each of which is incorporated herein by reference in its entirety.

### TECHNICAL FIELD

The present invention relates to an optoelectronic device and a method for manufacturing optoelectronic devices.

### BACKGROUND

In conventional optoelectronic devices, blue light is emitted from an LED (light emitting diode) semiconductor chip and converted into white light by means of phosphor particles contained in a conversion element. Radiation of the converted light in all directions is possible. The light emitted in all directions is not fully usable for an application or may even be detrimental depending on the requirements of the application. Depending on the geometry of the conversion element, such as the thickness of the conversion layer, and the arrangement of the phosphor particles in the conversion element, the light can be scattered in such a way that the radiation characteristic is inhomogeneous.

Light exiting the conversion element via the side flanks can be detrimental. This can result in a strong dependence of the brightness on the angle, a strong fluctuation of the color location over the angle as well as over the surface, an increased etendue as well as a reduced contrast between the luminous and non-luminous area.

The aforementioned optical properties can lead to difficulties in the application in which the optoelectronic device is used. In particular, a large color location scattering within a conversion element is disturbing and undesirable for applications with pixelated light sources in combination with imaging optics. For such applications, low color scatter, e.g. CxCy<±0.03, over the entire conversion element is necessary to minimize color gradients on the projected or imaged area.

### SUMMARY

Embodiments provide an optoelectronic device which can be manufactured inexpensively and which improves the radiation characteristics compared to conventional optoelectronic devices. Further embodiments provide a method for manufacturing optoelectronic devices.

An optoelectronic device comprises at least one optoelectronic component and a conversion element applied to a first main surface of the optoelectronic component. The conversion element comprises a frame of a reflective material and conversion material located within the frame. The frame laterally protrudes a light emitting area of the first main surface of the optoelectronic component. Consequently, the frame may laterally protrude the optoelectronic component.

The integration of the frame of the reflective material into the conversion element improves the radiation characteristics of the optoelectronic device without the need for further measures, such as the application of a reflective layer by means of a potting, dispensing, injection molding or baking step. Furthermore, the optoelectronic device can be manufactured in a cost-effective manner using the method for manufacturing described further below.

Furthermore, the optoelectronic device can be used to achieve improved brightness over the radiation angle, better color location behaviour over the angle, a more homogeneous color location over the surface, i.e., less scattering in the area of the outer edge of the conversion element, and a smaller etendue.

The reflective frame can be very compact and applied directly to the conversion layer of the conversion material, such that no surfaces or other design features, such as a cavity or stopper edges, need to be provided for it in the optoelectronic device.

The optoelectronic component can emit light in the visible range, ultraviolet (UV) light and/or infrared (IR) light. In particular, the optoelectronic component can be configured to generate blue light. Blue light has a wavelength approximately in the range of 450 nm to 490 nm.

Furthermore, the optoelectronic component can be an optoelectronic semiconductor component, in particular a semiconductor chip. For example, the optoelectronic component can be a light emitting diode (LED), an organic light emitting diode (OLED), a light emitting transistor, or an organic light emitting transistor. The optoelectronic component can also be part of an integrated circuit.

In addition to the optoelectronic component, other semiconductor components and/or other components can be integrated into the optoelectronic device.

The light emitting area can extend over the entire first main surface of the optoelectronic component. Alternatively, the light emitting area on the first main surface can be partially or completely surrounded by an edge that does not emit light. For example, the light emitting area can be the surface of an epitaxial layer.

The conversion material, also called converter material, is configured to transform or convert the light emitted by the optoelectronic component into light with a different wavelength. In other words, the conversion material is configured to convert a primary radiation generated by the optoelectronic component. Primary radiation entering the respective conversion layer in which the conversion material is located is at least partially converted into secondary radiation by the conversion material. In this case, the secondary radiation comprises wavelengths that differ from the wavelengths of the primary radiation, i.e., that are longer or shorter than the wavelengths of the primary radiation.

The conversion material can contain conversion particles that effect conversion of the light emitted from the optoelectronic component. For example, phosphor particles can be included as conversion particles in the conversion material. Phosphor can be used as a blue light converter to generate white light from the blue light.

The conversion particles can be embedded in a material or matrix, such as polysiloxane or silicone. The reflective material from which the frame is made can contain reflective particles. For example, the reflective particles can consist of titanium dioxide, TiO2.

The reflective particles can be embedded in a material or matrix, such as polysiloxane or silicone.

Due to its material properties, polysiloxane is particularly suitable as a matrix for the conversion particles or the reflective particles. Polysiloxane exhibits low viscosity, high temperature and UV stability, and compatibility with various fillers.

Reflective in this context means that the reflective particles are substantially reflective for at least part of the light emitted by the optoelectronic component or at least for light in a certain wavelength range.

It may be provided that the optoelectronic device consists only of the optoelectronic component and the conversion element applied thereto. Several such optoelectronic devices can, for example, be arranged on a foil and be delivered to a customer in this form.

Furthermore, it is possible that the optoelectronic device comprises an at least partially electrically conductive substrate on which the optoelectronic component is mounted. The substrate can be, for example, a leadframe. Furthermore, the substrate can be a so-called QFN (English: quad flat no leads package) flatmold. A QFN flatmold consists of a leadframe, in particular a coated copper leadframe, which is encapsulated by an encapsulation material, whereby the encapsulation material has the same height as the leadframe, i.e. no cavities are created. The substrate can further be a printed circuit board (PCB), a ceramic substrate or any other suitable substrate.

The electrical contact between the optoelectronic component and the substrate can be created using solder joints, bonding wires or other suitable contacts.

The optoelectronic component, the conversion element and, if applicable, the substrate can be encapsulated to form a housing or so-called package. For example, the components of the optoelectronic device can be encapsulated by means of a molding or dispensing process, in particular with a plastic, an epoxy resin or a silicone. Other packaging methods familiar to the skilled person are also possible.

Another advantage of the optoelectronic device is that reflective layers or frames can also be arranged within the conversion element. The conversion element can comprise multiple, separate regions of conversion material, each enveloped by the reflective material. In particular, the reflective material can be arranged within the frame in a grid-shaped manner. The conversion material can be arranged in the free spaces of the grid, i.e., the spaces between the reflective material.

In an optoelectronic component designed as a pixelated semiconductor chip, in particular as a pixelated LED semiconductor chip, a microstructure of conversion material is advantageous, since conversion material can be located above each pixel and this is surrounded by a frame of the reflective material. Further, different types of conversion material can be used so that light emitted from certain pixels is guided through different conversion material.

In this embodiment, the reflective material serves as a boundary between different light emitting areas of the pixelated semiconductor chip. The pixels of such a semiconductor chip can usually be driven individually.

This can increase the contrast between luminous and non-luminous areas or from pixel to pixel within an LED semiconductor chip.

The microstructure within the conversion element cannot be realized by downstream molding or dispensing processes. Due to the reflective layers between the individual pixelated areas of the LED semiconductor chip, the radiation characteristics, in particular the homogeneity of the color as well as of the brightness, can be further improved compared to a conversion element without microstructure, since the light guide effect between the pixels to be individually driven is thereby eliminated and neither color nor brightness between pixels is impaired. This also makes it possible to achieve a higher contrast between the individual pixels.

The optoelectronic device can be used in various applications, for example, vehicle headlights, flash lights, and/or stage lighting. Vehicle headlights, for example, can include LED semiconductor chips formed as surface emitters or multipixel LED semiconductor chips, on which the conversion elements described in the present application are mounted. Multipixel LED semiconductor chips with conversion elements containing multiple regions of the same or different conversion material can also be used for flash lights. The latter case makes it possible to produce different shades of white. LED semiconductor chips designed as surface emitters with conversion elements mounted on them can also be used for stage lighting, for example.

As described above, the conversion element is disposed on the first main surface of the optoelectronic component. The optoelectronic component can comprise a second main surface opposite the first main surface, and a plurality of side surfaces interconnecting the first and second main surface. In a rectangular configuration of the first main surface and the second main surface, the optoelectronic component includes exactly four side surfaces. The frame can laterally protrude over at least one of the side surfaces of the optoelectronic component. Further, the frame can protrude over all side surfaces or over exactly three of four side surfaces of the optoelectronic component.

One of the side surfaces of the optoelectronic component can span a plane, and an interface between the frame of the reflective material and the conversion material can lie in that plane. In other words, the interface between the frame and the conversion material lies in imaginary extension of the side surface of the optoelectronic component. This embodiment is particularly advantageous when the light emitting area extends over the entire first main surface of the optoelectronic component.

The same can apply for all other side surfaces or only for a total of three of four side surfaces of the optoelectronic component. That is, each of these side surfaces spans a respective plane in which a respective interface between the frame of the reflective material and the conversion material lies.

According to one embodiment, the conversion element comprises a first main planar surface and a second main planar surface opposite the first main surface. Further, the frame and a conversion layer containing the conversion material each comprise a first surface and a second surface opposite the first surface. The first surfaces of the frame and the conversion layer are each arranged in the first main surface of the conversion element, that is, the first surfaces of the frame and the conversion layer are flush. Further, the second surfaces of the frame and the conversion layer are each arranged in the second main surface of the conversion element. Consequently, the second surfaces are also flush.

The conversion layer containing the conversion material can be structured differently. According to a first variant, conversion particles are homogeneously distributed in the conversion layer. According to a second variant, the conversion particles are sedimented in the conversion layer. According to a third variant, the conversion layer can contain a first layer comprising conversion particles and a second layer comprising no conversion particles but, in particular comprising cured polysiloxone particles in polysiloxane.

A method for manufacturing optoelectronic devices includes the following steps.

First, a grid is provided which is made of a reflective material, i.e., grid nodes and grid webs of the grid which connect the grid nodes to each other are made of the reflective material. In the free spaces of the grid, i.e., the spaces between the grid nodes and grid webs, there is conversion material. The conversion material can fill the free spaces of the grid completely or only partially.

The grid is then separated to obtain conversion elements. For separating, the grid can be separated or subdivided mechanically, for example by sawing or punching. The resulting individual conversion elements can have the shape of the conversion element of the optoelectronic device described above. In particular, the grid can be separated such that the conversion elements each comprise an outer frame made of the reflective material. Further, the conversion elements can each comprise a microstructure in which regions of the conversion material are each enveloped by the reflective material.

The conversion elements are then applied to optoelectronic components. In particular, a respective conversion element can be glued onto a respective optoelectronic component by means of a suitable adhesive, e.g. a silicone adhesive. This creates optoelectronic devices as described above.

The method for manufacturing optoelectronic devices can comprise the optoelectronic device embodiments described above.

The step after which the grid is provided from the reflective material can comprise first making the grid from the reflective material and then filling the conversion material into the free spaces of the grid.

To produce the grid, the reflective material can be filled into a molding. The reflective material, which contains suitable reflective elements or particles, for example of titanium dioxide, TiO₂, as well as a material in which the reflective elements or particles are embedded, can be poured into a molding in a liquid state and distributed in the molding, in particular with the aid of a squeegee. After drying and curing of the grid, the grid can be released from the molding.

In particular, if the grid is produced using a molding and a squeegee process as described above, both the grid and the conversion material can each be produced of polysiloxane. This ensures good adhesion or compatibility within the conversion elements to be produced.

Alternatively, the grid can also be prefabricated, for example by means of potting, dispensing, injection molding or other suitable techniques. The use of these techniques allows special designs of the grid, e.g. undercuts, radii and surface geometries. Furthermore, the grid can be produced of different materials, e.g. silicone, epoxy or aluminum.

According to one embodiment, to produce the grid filled with the conversion material, a layer of the conversion material is first produced. Subsequently, a grid-shaped recess is formed in the layer of the conversion material. In particular, a mechanical process, such as a sawing process, is used to remove conversion material from the layer. Finally, the reflective material is filled into the grid-shaped recess to obtain the grid with the conversion material in the free spaces of the grid.

According to an alternative embodiment, at least one layer of conversion material is produced for producing the grid filled with the conversion material, and the at least one layer of conversion material is divided into segments, for example by means of sawing. Subsequently, the segments are arranged in a grid pattern, for example by means of a positioning system or a pick-and-place system, in such a way that there are spaces for the later grid between the segments. The reflective material is filled into the spaces between the segments arranged in a grid pattern.

The above embodiment can be further developed by forming at least two layers of different conversion materials and dividing these layers into segments. Subsequently, the segments of the at least two layers are arranged in one and the same grid pattern, i.e., the grid pattern contains segments of different conversion materials. The reflective material is filled into spaces between the segments arranged in a grid pattern.

### BRIEF DESCRIPTION OF THE DRAWINGS

In the following, embodiments of the invention are explained in more detail with reference to the accompanying drawings.

FIGS. 1A to 1C show illustrations of an embodiment of an optoelectronic device with an LED semiconductor chip and a conversion element;

FIGS. 2A and 2B show illustrations of an embodiment of an optoelectronic device comprising an LED semiconductor chip and a conversion element having a microstructure;

FIG. 3 shows an illustration of an embodiment of an optoelectronic device comprising an LED semiconductor chip, a conversion element, a substrate, and a housing;

FIGS. 4A to 4C show illustrations of embodiments of an optoelectronic device comprising an LED semiconductor chip and a punched or displaced conversion element or a conversion element without a frame on one side;

FIGS. 5A to 5C show illustrations of an embodiment of a grid filled with a conversion material of a reflective material;

FIGS. 6A and 6B show illustrations of an embodiment of a method for manufacturing a grid from a reflective material;

FIGS. 7A to 7E show illustrations of an embodiment of a method for manufacturing conversion elements;

FIGS. 8A to 8E show illustrations of a further embodiment of a method for manufacturing conversion elements; and

FIGS. 9A to 9D show illustrations of a further embodiment of a method for manufacturing conversion elements.

### DETAILED DESCRIPTION OF ILLUSTRATIVE EMBODIMENTS

In the following detailed description, reference is made to the accompanying drawings, which form a part of this description and in which specific embodiments in which the invention may be practiced are shown for illustrative purposes. Since components of embodiments may be positioned in a number of different orientations, the directional terminology is for illustrative purposes and is not limiting in any way. It is understood that other embodiments may be used and structural or logical changes may be made without departing from the scope of protection. It is understood that the features of the various embodiments described herein may be combined with each other, unless specifically indicated otherwise. Therefore, the following detailed description is not to be construed in a limiting sense. In the figures, identical or similar elements are provided with identical reference signs where appropriate.

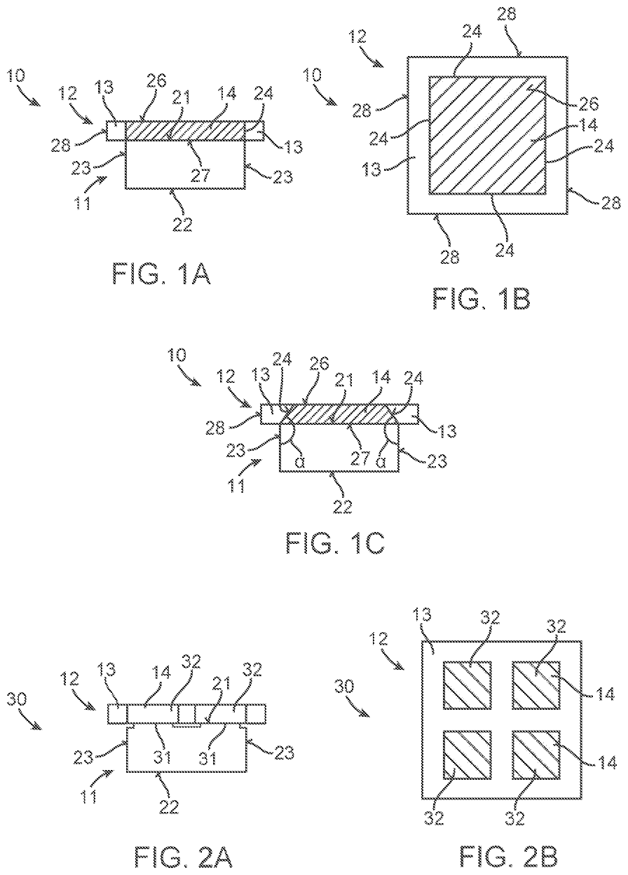

FIG. 1A schematically shows an optoelectronic device 10 in a cross-section. FIG. 1B shows the optoelectronic device 10 in a top view from above.

The optoelectronic device 10 includes an optoelectronic component in the form of an LED semiconductor chip 11 and a conversion element 12. The conversion element 12 includes a frame 13 made of a reflective material and conversion material 14 located in the frame 13.

The LED semiconductor chip 11 has a first main surface 21, a second main surface 22 opposite the first main surface 21, and four side surfaces 23 connecting the first and second main surfaces 21, 22.

The conversion element 12 is provided on the first main surface 21 of the LED semiconductor chip 11. In the present embodiment, the light emitting area of the LED semiconductor chip 11 extends over the entire first main surface 21. Alternatively, the light emitting area on the first main surface 21, which can be an epitaxial layer, can be surrounded by a chip edge that does not emit light.

The frame 13 of the conversion element 12 laterally protrudes the first main surface 21 of the LED semiconductor chip 11, i.e., the frame 13 protrudes the first main surface 21 or the light emitting area of the first main surface 21. In the present embodiment, the frame 13 protrudes all four side surfaces 23 of the LED semiconductor chip 11.

Imaginary, each of the side surfaces 23 of the LED semiconductor chip 11 spans a plane. An interface 24 between the frame 13 and the conversion material 14 comprises four portions due to the rectangular shape of the layer of the conversion material 14. Each of these portions of the interface 24 lies in one of the planes spanned by the side surfaces 23 of the LED semiconductor chip 11. Consequently, the outline of the layer of the conversion material 14 shown in FIG. 1B corresponds to the outline of the LED semiconductor chip 11 when viewed from above. If the light emitting area on the first main surface 21 is surrounded by a chip edge that does not emit light, the outline of the layer of the conversion material 14 shown in FIG. 1B may correspond to the outline of the light emitting area.

Further, the conversion element 12 comprises a first main planar surface 26 and a second main planar surface 27 opposite the first main planar surface 26, wherein the second main planar surface 27 of the conversion element 12 having is applied to the LED semiconductor chip 11. The frame 13 and the layer of conversion material 14 each have surfaces that lie in the first main planar surface 26 and the second main planar surface 27, respectively. That is, the frame 13 and the layer of conversion material 14 are flush with both the top surface and the bottom surface of the conversion element 12.

The frame 13 includes four side surfaces 28 interconnecting the first main surface 26 and the second main surface 27 of the conversion element 12. It may be provided that one, two, three or all of the four side surfaces 28 of the frame 13 are perpendicular to the first and second main surfaces 26, 27 of the conversion element 12.

The reflective material from which the frame 13 is made contains reflective particles of titanium dioxide, TiO₂, embedded in a matrix of polysiloxane.

Conversion material 14 contains phosphor particles that are also embedded in a matrix of polysiloxane.

The LED semiconductor chip 11 is a surface emitter that emits light, especially blue light, only on its top surface. Furthermore, the LED semiconductor chip 11 can also be a volume emitter that emits light on its top surface and side surfaces. The light emitted from the LED semiconductor chip 11 is converted into white light by the conversion material 14. By means of the frame 13 made of the reflective material, the desired radiation characteristic can be created.

The interfaces 24 between the frame 13 and the conversion material 14 do not necessarily have to be oriented perpendicular to the first or second main surface 26, 27 of the conversion element 12, but can also run slanted to the main surfaces 26, 27, as exemplarily shown in FIG. 1C. One, two, three or all four interfaces 24 form an angle α, in particular an inner angle α, with the respective side surface 23 of the LED semiconductor chip 11, which is smaller than 180° and in particular larger than 90°. This achieves a bundling of the emitted light, the etendue is reduced and a higher radiant intensity is achieved. This brings advantages in particular for applications with optics.

FIGS. 2A and 2B schematically show an optoelectronic device 30 in a cross-sectional view and a top view, respectively. The optoelectronic device 30 is substantially identical to the optoelectronic device 10 shown in FIGS. 1A and 1B, except for the differences noted below.

In the optoelectronic device 30, the LED semiconductor chip 11 is a pixelated semiconductor chip having a plurality of pixels 31, such as four pixels 31, which can be individually controlled.

The conversion element 12 includes a plurality of independent regions 32 of the conversion material 14, each of which is enveloped by the reflective material from which the frame 13 is also formed. Each of the regions 32 is arranged above a respective pixel 31.

Further, it can be provided that different types of conversion material 14 are used for selected regions 32 so that light emitted from certain pixels 31 is guided through different conversion material 14.

In the optoelectronic device 30, the reflective material serves as a boundary between different light emitting areas of the pixelated LED semiconductor chip 11.

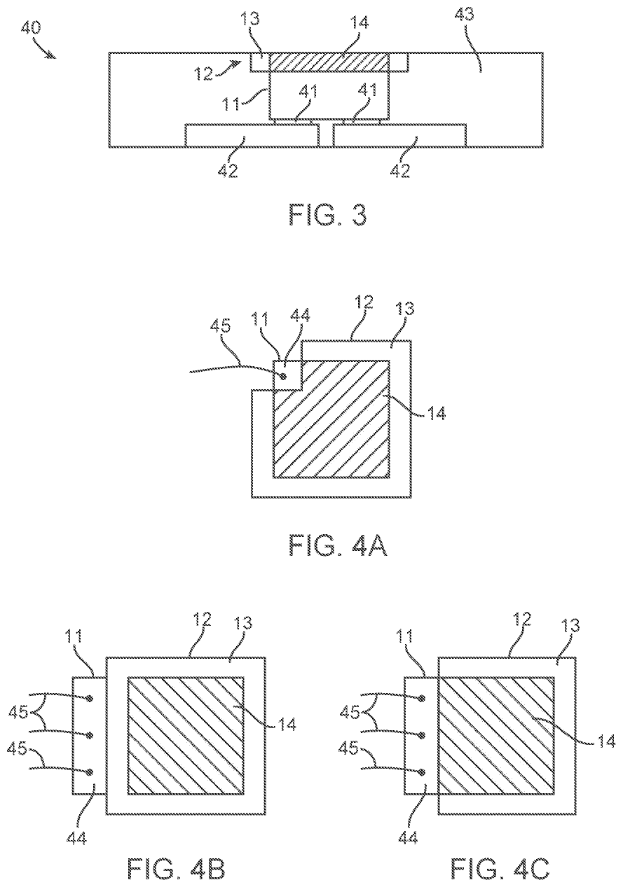

FIG. 3 schematically shows a cross-sectional view of an optoelectronic device 40. The optoelectronic device 40 includes the LED semiconductor chip 11 and the conversion element 12 of FIGS. 1A and 1B.

In the present embodiment, the LED semiconductor chip 11 is a so-called flip chip, which has all electrical contact elements 41 on its bottom surface. The LED semiconductor chip 11 is soldered with its electrical contact elements 41 onto a substrate 42, for example a lead frame. Furthermore, the LED semiconductor chip 11, the conversion element 12 and the substrate 42 are suitably encapsulated to form a housing 43.

FIGS. 4A to 4C show sections of optoelectronic devices similar to the optoelectronic device 10 described above, but in which the LED semiconductor chip 11 has at least one electrical contact element 44 on its top surface.

In order to expose the electrical contact element 44 on the top surface of the LED semiconductor chip 11 and to allow it to be contacted by means of a bonding wire 45, a corner of the conversion element 12 has been punched out in FIG. 4A. If there are multiple electrical contact elements 44 on the top surface of the LED semiconductor chip 11, one or more additional corners of the conversion element 12 may be punched out. Instead of a punching process, the corners or regions of the conversion element 12 can also be removed by means of a laser beam, or the conversion element 12 can be manufactured in such a way that the corresponding corners or regions are not present from the outset.

In FIG. 4B, an electrical contact element 44 extends along an edge at the top surface of the LED semiconductor chip 11. Here, the conversion element 12 is correspondingly shifted to allow contacting of the electrical contact element 44 with bonding wires 45.

Not all four sides of the conversion element 12 need to have a frame 13 of the reflective material. Depending on the chip type or application requirements, only one, two or three sides of the conversion material 14 can be surrounded by the frame 13. FIG. 4C shows an embodiment in which that side of the conversion element 12 does not have a frame 13 on which the bonding wires 45 are located.

The following describes embodiments of methods by which the above-described optoelectronic devices 10, 30, and 40 can be manufactured.

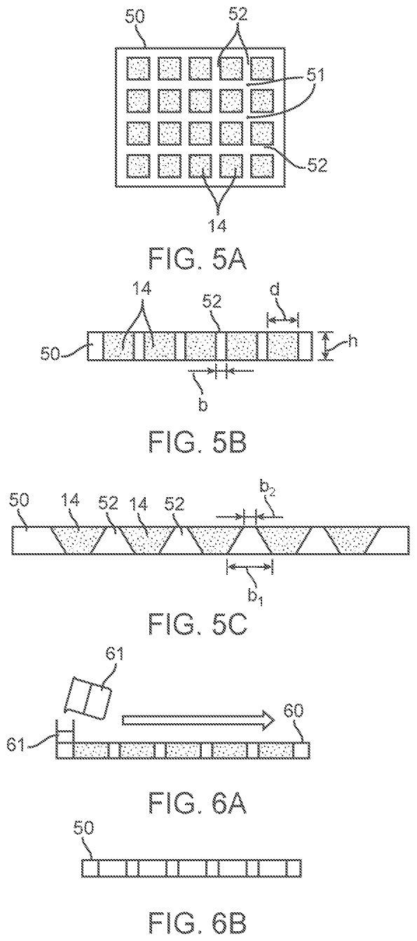

First, a grid 50 is provided, as exemplified by a top view in FIG. 5A and a cross-sectional view in FIG. 5B.

The grid 50 is made of a reflective material, i.e., grid nodes 51 and grid webs 52, which connect the grid nodes 51 to each other, are made of the reflective material. In free spaces of the grid, i.e., the spaces between the grid nodes 51 and the grid webs 52, there is located conversion material 14.

The height h of the grid 50 can be in the range from about 10 μm to about 150 μm. The web width b can be in the range of about 5 μm to about 500 μm. The width d of free space of the grid depends on the chip size and can be in the range of about 0.1 mm to about 2 mm. Values for height h, web width b and width d outside the above ranges are also possible.

The grid webs 52 can extend perpendicular to the main surfaces of the grid 50 or may be arranged at an angle, as shown by way of example in FIG. 5C. There, the grid webs 52 taper from one main surface of the grid 50 toward the other main surface. For example, the grid webs 52 on one main surface of the grid 50 may have a width b1 that is greater than the width b2 of the grid webs 52 on the other main surface of the grid 50. Depending on the application, the grid 50 can be mounted on an optoelectronic component with one or the other main surface.

FIGS. 6A and 6B show an embodiment of a method for manufacturing the grid 50.

Reflective material 61, for example polysiloxane or silicone filled with titanium dioxide or another reflective material, is incorporated in a liquid state into a molding 60 by means of squeegeeing, as shown in FIG. 6A. The molding 60 has the dimensions of the later grid 50, and the squeegee can be moved over the molding 60 or the molding 60 can be moved relative to the squeegee.

After drying and curing, the grid 50 shown in FIG. 6B can be released from the molding 60.

Alternatively, the grid 50 can be prefabricated and made from silicone, epoxy, aluminum or other materials, for example, by molding, dispensing, injection molding or other suitable techniques.

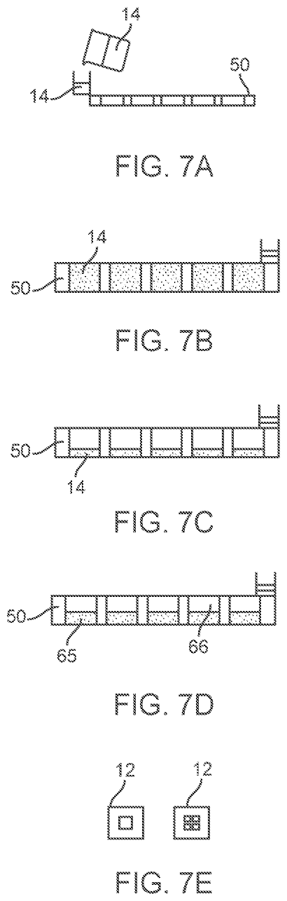

FIGS. 7A to 7E show an embodiment of a method for manufacturing conversion elements 12.

FIG. 7A shows that liquid conversion material 14 is filled into the grid 50 of the reflective material by means of squeegeeing. The conversion material 14 contains phosphor particles in a matrix of polysiloxane.

The conversion layer formed from the conversion material 14 in the grid 50 may have different structures.

As FIG. 7B shows, the phosphor particles may be homogeneously distributed in the conversion material 14 of the conversion layer to achieve volume conversion.

Alternatively, the phosphor particles in the conversion layer may sediment after the conversion material 14 is introduced into the grid 50 and before the conversion material 14 is cured. Such a conversion layer is exemplified in FIG. 7C.

According to another variant shown in FIG. 7D, a double layer is produced by squeegeeing twice in a row. First, a first layer 65 containing polysiloxane with phosphor particles is produced, and then a second layer 66 is produced which does not contain phosphor particles but cured polysiloxone particles in polysiloxane.

After the conversion material 14 has cured, the grid 50 can be separated by sawing or punching and the conversion elements 12 shown in FIG. 7E are obtained, which contain only a frame 13 of the reflective material as in FIG. 1B or an additional microstructure of the reflective material within the frame 13 as in FIG. 2B. The conversion elements 12 with the additional microstructure can be used for pixelated light sources.

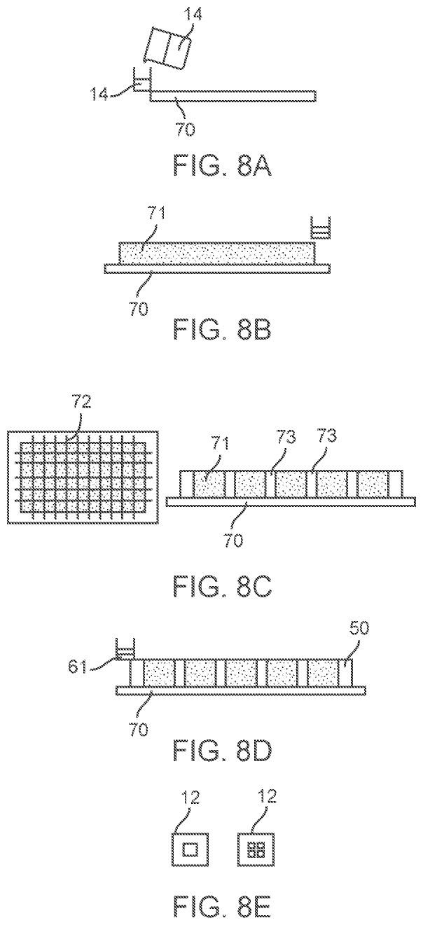

The conversion elements 12 are then bonded to the LED semiconductor chips 11. FIGS. 8A to 8E show another embodiment of a method for manufacturing conversion elements 12.

FIG. 8A shows that conversion material 14 is first squeegeed onto a foil 70. Here, too, the conversion material 14 may comprise phosphor particles embedded in poylsiloxane.

A layer 71 is obtained by applying the conversion material 14 to the foil 70. The phosphor particles may be homogeneously distributed in the layer 71, as shown in FIG. 8B. Alternatively, the phosphor particles may sediment in the layer 71 before the conversion material 14 is cured, or the layer 71 may comprise a double layer as shown in FIG. 7D, wherein a first layer contains polysiloxane with phosphor particles and a second layer does not contain phosphor particles but contains cured polysiloxone particles in polysiloxane.

Subsequently, as shown in FIG. 8C, a grid-shaped recess or grid pattern 72 is made in the layer 71 by removing material from the layer 71, for example by sawing. This creates individual segments from the layer 71, as well as spaces 73 between the segments.

According to FIG. 8D, the spaces 73 are filled with the reflective material 61, e.g. polysiloxane with titanium dioxide particles, by squeegeeing to finally create the grid 50.

The grid 50 can be separated by sawing or punching to obtain the conversion elements 12 shown in FIG. 8E with or without microstructure.

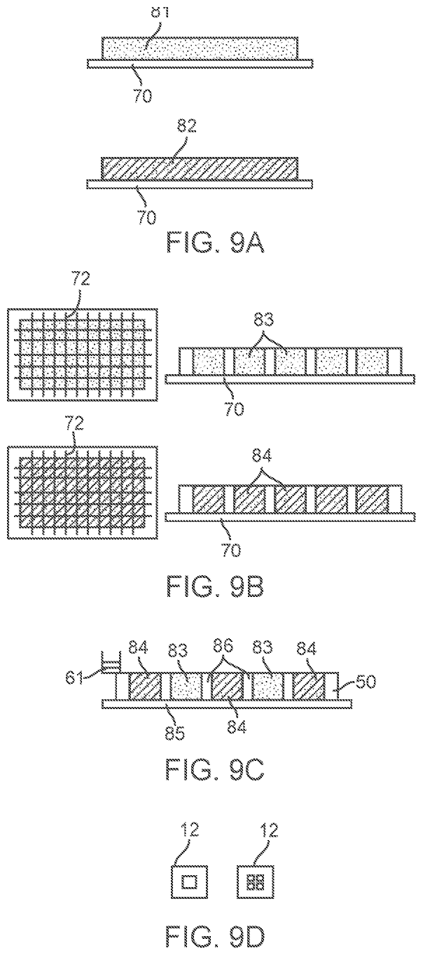

FIGS. 9A to 9D show another embodiment of a process for manufacturing conversion elements 12, which is similar in large parts to the method shown in FIGS. 8A to 8E.

FIG. 9A shows that, analogous to FIGS. 8A and 8B, two layers 81, 82 of conversion material are generated on foils 70 by squeegeeing. The layers 81, 82 can differ from each other, for example, by different conversion particles or different conversion solutions.

According to FIG. 9B, a grid-shaped recess or grid pattern 72 is made in both layers 81, 82 by sawing to create individual segments 83 from layer 81 and individual segments 84 from layer 82.

Subsequently, the segments 83 and 84 are arranged together, for example with the aid of a positioning system or a pick-and-place system, in a grid pattern on a foil 85 in such a way that spaces 86 for the later grid 50 are located between the segments 83, 84, as shown in FIG. 9C.

According to FIG. 9C, the spaces 86 are filled with the reflective material 61, e.g. polysiloxane with titanium dioxide particles, by squeegeeing to finally create the grid 50.

Subsequently, the grid 50 is separated by sawing or punching to obtain the conversion elements 12 shown in FIG. 9E with or without microstructure.

The optoelectronic devices described in the present application can be used, for example, in headlights for vehicles, flash lights and/or stage lighting. For vehicle headlights, LED semiconductor chips designed as surface emitters with conversion elements according to FIGS. 1, 3 and 4 or multipixel LED semiconductor chips with conversion elements according to FIGS. 2, 3 and 4 are particularly suitable. For flash lights, multipixel LED semiconductor chips can be used in conjunction with conversion elements according to FIGS. 2, 3, 4 and 9. For stage lighting, for example, LED semiconductor chips designed as surface emitters with conversion elements mounted on them can be used according to FIGS. 1, 3 and 4.

Although the invention has been illustrated and described in detail by means of the preferred embodiment examples, the present invention is not restricted by the disclosed examples and other variations may be derived by the skilled person without exceeding the scope of protection of the invention.

1.-15. (canceled)

16. An optoelectronic device comprising:
an optoelectronic component with a first main surface, a second main surface and a plurality of side surfaces interconnecting the first and second main surfaces; and
a conversion element arranged at the first main surface of the optoelectronic component,
wherein the conversion element comprises a frame of a reflective material and a conversion material located within the frame,
wherein an interface between the frame and the conversion material runs slanted having an angle of smaller than 180° and larger than 90° between the interface and an adjacent side surface of the plurality of side surfaces, and
wherein the frame protrudes laterally beyond a light emitting area of the first main surface of the optoelectronic component.

17. The optoelectronic device according to claim 16, wherein the conversion element comprises a plurality of regions of the conversion material each enveloped by the reflective material.

18. The optoelectronic device according to claim 16, wherein the frame protrudes laterally beyond at least one of the side surfaces of the optoelectronic component.

19. The optoelectronic device according to claim 16,
wherein the conversion element comprises a first main planar surface and a second main planar surface opposite the first main planar surface,
wherein the frame and a conversion layer of the conversion element containing the conversion material each have a first surface and a second surface opposite the first surface,
wherein the first surfaces of the frame and the conversion layer are each arranged in the first main planar surface of the conversion element, and
wherein the second surfaces of the frame and the conversion layer are each arranged in the second main planar surface of the conversion element.

20. The optoelectronic device according to claim 16,
wherein the conversion element comprises a conversion layer containing the conversion material.

21. The optoelectronic device according to claim 20,
wherein conversion particles are homogeneously distributed in the conversion layer or conversion particles are sedimented in the conversion layer or the conversion layer comprises a first layer comprising conversion particles and a second layer comprising no conversion particles.

22. A method for manufacturing optoelectronic devices, the method comprising:
providing a grid of a reflective material, wherein a conversion material is located in free spaces of the grid;
separating the grid to obtain conversion elements; and
applying the conversion elements to optoelectronic components.

23. The method according to claim 22, wherein the grid is first made of the reflective material and the conversion material is subsequently filled into the free spaces of the grid.

24. The method according to claim 23, wherein the reflective material is filled into a molding to produce the grid.

25. The method according to claim 22, wherein a layer of the conversion material is formed to produce the grid, wherein a grid-shaped recess is formed in the layer of the conversion material, and wherein the reflective material is filled into the grid-shaped recess.

26. The method according to claim 22, wherein at least one layer of the conversion material is formed to produce the grid, wherein the at least one layer of the conversion material is divided into segments, wherein the segments are arranged in a grid pattern, and wherein the reflective material is filled into spaces between the segments arranged in a grid pattern.

27. The method according to claim 22, wherein at least two layers of different conversion materials are formed to produce the grid, wherein the at least two layers of different conversion materials are divided into segments, wherein the segments of the at least two layers of different conversion materials are arranged in a grid pattern, and wherein the reflective material is filled into spaces between the segments arranged in a grid pattern.

28. The method according to claim 22, wherein the grid and the conversion material each comprise polysiloxane.

29. The method according to claim 22, wherein the conversion elements each comprise an outer frame of the reflective material.

30. The method according to claim 22, wherein the conversion elements each comprise a plurality of regions of the conversion material each enveloped by the reflective material.
